(19) United States
(12) Patent Application Publication
(10) Pub. No.: US 2024/0418752 A1
(43) Pub. Date: Dec. 19, 2024

(54) CURRENT SENSOR AND CURRENT DETECTION METHOD

(71) Applicant: Asahi Kasei Microdevices Corporation, Tokyo (JP)

(72) Inventor: Ryuji NOBIRA, Tokyo (JP)

(21) Appl. No.: 18/822,313

(22) Filed: Sep. 2, 2024

Related U.S. Application Data
(63) Continuation of application No. PCT/JP2023/006676, filed on Feb. 24, 2023.

(30) Foreign Application Priority Data
Mar. 3, 2022 (JP) 2022-033016

(51) Int. Cl. G01R 15/20

(52) U.S. Cl. CPC G01R 15/207

(57) ABSTRACT

A signal processing circuit of a current sensor has: a voltage detection circuit which detects a common mode voltage obtained by combining voltages of first signals respectively outputted from the pair of first output terminals; a differential amplifier circuit which outputs a signal obtained by amplifying each of the first signals with a predetermined gain, when the common mode voltage is equal to or lower than a predetermined threshold voltage, and which outputs a signal obtained by amplifying each of the first signals with a gain lower than a predetermined gain, when the common mode voltage exceeds the predetermined threshold voltage; and a correction circuit which corrects an output signal of the differential amplifier circuit, and the signal processing circuit derives a current value of the current flowing through the conductor, based on the output signal corrected by the correction circuit.

The contents of the following patent application(s) are incorporated herein by reference:
NO. 2022-033016 filed in JP on Mar. 3, 2022
NO. PCT/JP2023/006676 filed in WO on Feb. 24, 2023

### BACKGROUND

### 1. Technical Field

The present invention relates to a current sensor and a current detection method.

### 2. Related Art

Patent Document 1 discloses a current sensor including: a conductor through which a to-be-measured current flows; two magnetoelectric conversion elements arranged opposite to each other near the conductor; and an insulating member which supports the two magnetoelectric conversion elements, where the conductor is arranged so as not to come into contact with the insulating member and not to support the insulating member. Patent Document 2 discloses a current sensor which controls output of a magnetizing field sensor integrated circuit based on detection of a transient voltage.

### PRIOR ART DOCUMENT

### Patent Document

Patent Document 1: Japanese Patent No. 6321800
Patent Document 2: U.S. Patent Application Publication No. 2018/0149713

### BRIEF DESCRIPTION OF THE DRAWINGS

FIG. 1A is a top view showing one example of a current sensor 100.

FIG. 1B is a cross sectional view taken along a line J-J′ of the current sensor 100 shown in FIG. 1A.

FIG. 2 is a diagram showing one example of functional blocks of a current sensor 100 including a signal processing IC 120.

FIG. 3 is a diagram showing one example of functional blocks of a current sensor 300 including a signal processing IC 120 according to a first embodiment.

FIG. 4 is a diagram showing one example of a more specific circuit configuration of the current sensor 300.

FIG. 5 is a diagram showing one example of a specific circuit configuration of a common mode voltage detection circuit 30.

FIG. 6 is a diagram showing one example of specific operations of the current sensor 300 shown in FIG. 3 and FIG. 5.

FIG. 7 is a diagram showing one example of functional blocks of a current sensor 600 including a signal processing IC 120 according to a second embodiment.

FIG. 8 is a diagram showing one example of a more specific circuit configuration of the current sensor 600.

FIG. 9 is a diagram showing one example of specific operations of the current sensor 600 shown in FIG. 7 and FIG. 8.

FIG. 10 is a diagram showing one example of functional blocks of a current sensor 1000 including a signal processing IC 120 according to a third embodiment.

FIG. 11 is a diagram showing one example of functional blocks of a current sensor 1100 including a signal processing IC 120 according to a fourth embodiment.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

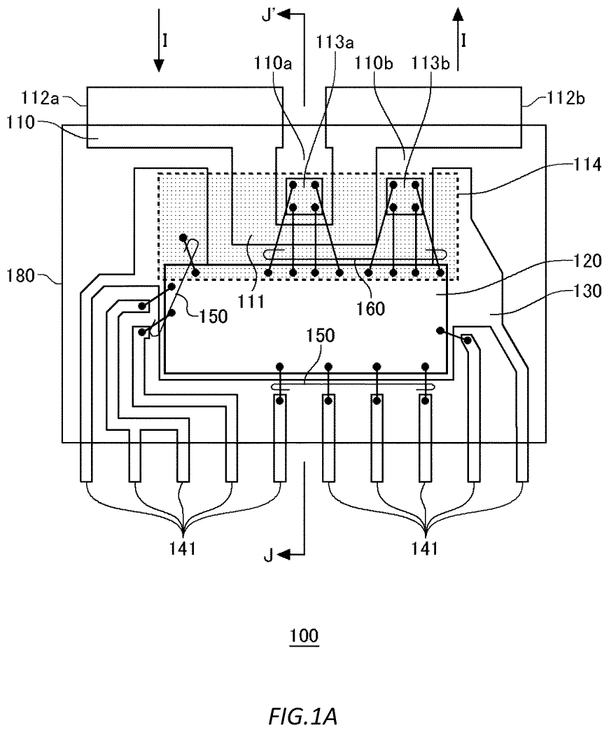

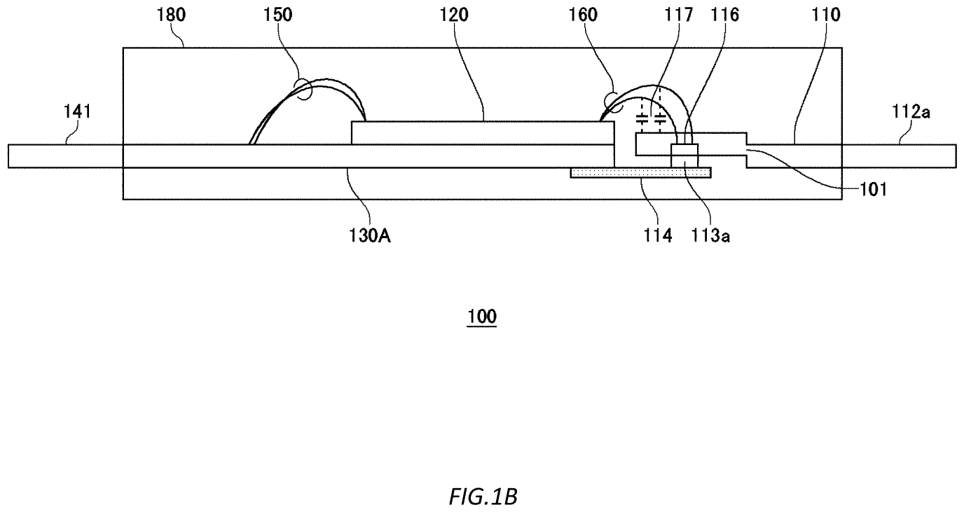

FIG. 1A is a top view showing one example of a current sensor 100. FIG. 1B is a cross sectional view taken along a line J-J′ of the current sensor 100 shown in FIG. 1A. The current sensor 100 includes a conductor 110, a first magnetoelectric conversion element 113a, a second magnetoelectric conversion element 113b, a signal processing IC 120, and a metal plate 130.

The conductor 110 has two lead terminals 112a and 112b. A to-be-measured current I flows through the conductor 110. The conductor 110 has a U-shaped current path 111 through which the to-be-measured current I flows in a circumferential direction from a side of the lead terminal 112a toward a side of the lead terminal 112b. The first magnetoelectric conversion element 113a is arranged in a gap 110a of the conductor 110 located inside the U-shaped current path 111. The second magnetoelectric conversion element 113b is arranged with the current path 111 interposed between the first magnetoelectric conversion element 113a and the second magnetoelectric conversion element 113b. The first magnetoelectric conversion element 113a and the second magnetoelectric conversion element 113b are arranged opposite to each other with the conductor 110 interposed therebetween, and they each output a signal according to a magnetizing field.

The signal processing IC 120 is supported by the metal plate 130 insulated from the conductor 110. The metal plate 130 includes a U-shaped portion, and a U-shaped portion of the current path 111 is arranged in the U-shape of the metal plate 130. The second magnetoelectric conversion element 113b is arranged in a gap 110b between the U-shaped portion of the current path 111 and the U-shaped portion of the metal plate 130. The first magnetoelectric conversion element 113a and the second magnetoelectric conversion element 113b may be each, for example, a hall element, a magnetoresistance effect element, a hall IC, or a magnetoresistance effect IC.

The conductor 110, a lead terminal 141, the signal processing IC 120, the first magnetoelectric conversion element 113a, and the second magnetoelectric conversion element 113b are sealed with mold resin 180 and formed as the same package, as shown in FIG. 1B. The mold resin 180 is mold resin such as epoxy resin.

In such a current sensor 100, when the to-be-measured current I flows through the conductor 110, a magnetic field is generated according to an amount and a direction of a current flowing through the U-shaped portion formed in the current path 111. Here, the first magnetoelectric conversion element 113a is arranged in the gap 110a near the U-shaped portion of the current path 111. Therefore, the first magnetoelectric conversion element 113a will detect a magnetic flux density generated by the to-be-measured current I flowing through the conductor 110, to output an electrical signal according to the magnetic flux density to the signal processing IC 120.

In addition, the second magnetoelectric conversion element 113b will also detect a magnetic flux density generated by the to-be-measured current I flowing through the conductor 110, to output an electrical signal according to the magnetic flux density to the signal processing IC 120. In this manner, the first magnetoelectric conversion element 113a and the second magnetoelectric conversion element 113b each detect a current, according to the to-be-measured current I flowing through the conductor 110.

The first magnetoelectric conversion element 113a and the second magnetoelectric conversion element 113b are respectively arranged apart from the conductor 110 by the gaps 110a and 110b, and are not in contact with the conductor 110 at any time. As a result, there is no electrical continuity between the conductor 110 and the first magnetoelectric conversion element 113a as well as between the conductor 110 and the second magnetoelectric conversion element 113b, and a space (clearance) is secured to maintain insulation. In addition, the first magnetoelectric conversion element 113a is supported by an insulating member 114 indicated by a broken line in FIG. 1A. The insulating member 114 may be, for example, an insulating tape made of a polyimide material with a high dielectric strength voltage.

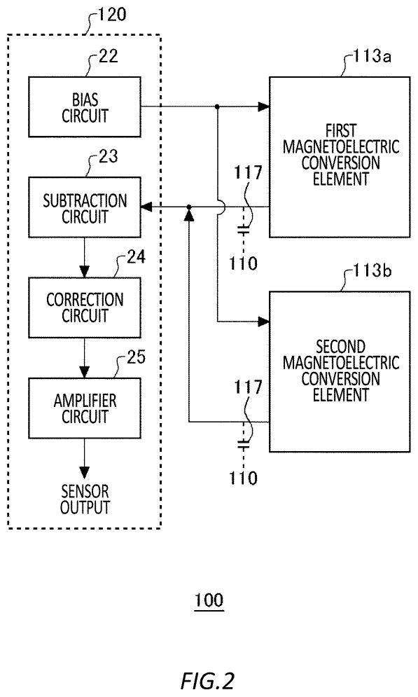

The first magnetoelectric conversion element 113a and the second magnetoelectric conversion element 113b are electrically connected to the signal processing IC 120 via a wire 160 which is a conductive wire such as a metal wire. The signal processing IC 120 is electrically connected to the lead terminal 141 via a wire 150 which is a conductive wire such as a metal wire. The signal processing IC 120 may be composed of, for example, a large scale integration (LSI). The signal processing IC 120 includes, for example, a memory, a processor, a bias circuit, a subtraction circuit, a correction circuit, an amplifier circuit, and the like. This configuration of the signal processing IC 120 is shown in a detailed functional block diagram in FIG. 2 which will be described later.

In the side view taken along the line J-J′ of the current sensor 100 shown in FIG. 1B, the insulating member 114 is joined to a part of a back surface 130A of the metal plate 130, and is formed to support the first magnetoelectric conversion element 113a. Although FIG. 1B shows only the first magnetoelectric conversion element 113a, the insulating member 114 supports the second magnetoelectric conversion element 113b as well as the first magnetoelectric conversion element 113a.

A level difference 101 is formed at a part of a back surface of the conductor 110, and due to this level difference 101, the conductor 110 is arranged so as not to come into contact with the insulating member 114 at any time. The mold resin 180 is filled between the back surface of the conductor 110 and the insulating member 114. The insulating member 114 is made of, for example, an insulating tape of a polyimide material with excellent pressure resistance, and is attached to the back surface 130A of the metal plate 130 and supports the first magnetoelectric conversion element 113a from the back surface, in a state as shown in in FIG. 1B.

The conductor 110 and the first magnetoelectric conversion element 113a are provided on the same surface of the insulating member 114. In addition, a height position of a magnetosensitive surface 116 of the first magnetoelectric conversion element 113a is arranged between heights of a bottom surface and a top surface of the conductor 110, for example, at a center of a distance from the bottom surface to the top surface.

The first magnetoelectric conversion element 113a and the second magnetoelectric conversion element 113b are electrically connected to the signal processing IC 120 via the wire 160 which is a conductive wire such as a metal wire. However, due to the above structure, the conductor 110 and the wire 160 will be electrically joined by a parasitic capacitance 117.

FIG. 2 is a diagram showing one example of functional blocks of a current sensor 100 including a signal processing IC 120. The signal processing IC 120 includes a bias circuit 22, a subtraction circuit 23, a correction circuit 24, and an amplifier circuit 25. The bias circuit 22 is connected to a first magnetoelectric conversion element 113a and a second magnetoelectric conversion element 113b, and supplies power to the first magnetoelectric conversion element 113a and the second magnetoelectric conversion element 113b. In other words, the bias circuit 22 applies an excitation current to (causes an excitation current to flow into) the first magnetoelectric conversion element 113a and the second magnetoelectric conversion element 113b.

The subtraction circuit 23 calculates a current value by cancelling an influence of an externally generated magnetic field, that is, by cancelling out common mode noise, based on a difference between an output of the first magnetoelectric conversion element 113a and an output of the second magnetoelectric conversion element 113b. In addition, a transient high voltage (dvdt) is applied to a conductor 110, and voltage noise propagating via a parasitic capacitance 117 is also cancelled out.

The correction circuit 24 corrects an output value from the subtraction circuit 23. For example, the correction circuit 24 corrects output values of the first magnetoelectric conversion element 113a and the second magnetoelectric conversion element 113b, according to a temperature correction coefficient preliminarily stored in a memory, based on operating temperature. The correction circuit 24 may perform offset correction based on an absolute value of a zero current voltage (open circuit voltage (OCV)) of the current sensor 100, and offset correction through temperature drift. The amplifier circuit 25 amplifies an output value from the correction circuit 24.

Since the current sensor 100 with a configuration as described above calculates the current value based on the difference between the outputs of the first magnetoelectric conversion element 113a and the second magnetoelectric conversion element 113b, it is possible to cancel the influence of the externally generated magnetic field. That is, according to the current sensor 100 with a configuration as described above, in an ideal case, an influence of the transient high voltage (dvdt) applied to the conductor 110 will not be visible. However, in case of wire deformation during mold resin filling or deviation during assembly, balance of the parasitic capacitance 117 will be lost, and the propagating voltage noise will not be cancelled out but will be amplified and outputted.

Therefore, in order to reduce the influence of the transient voltage applied to the conductor 110, structural measures are taken to equalize the parasitic capacitance. However, the structural measures alone cannot sufficiently suppress the influence of the transient voltage. Therefore, with development of a power device, it is desired to realize a good current transient response characteristic for the transient voltage to the conductor due to switching of the power device with its speed and voltage further increased.

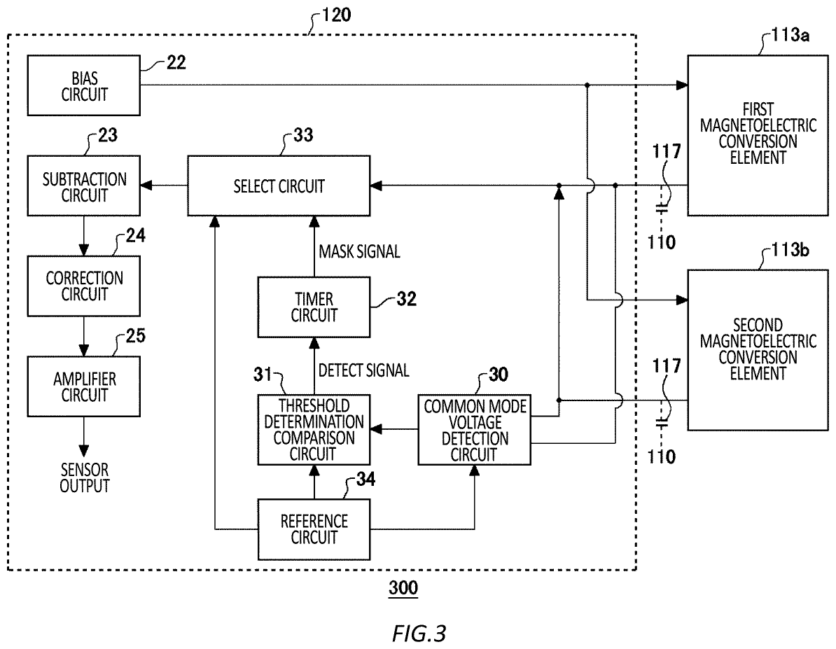

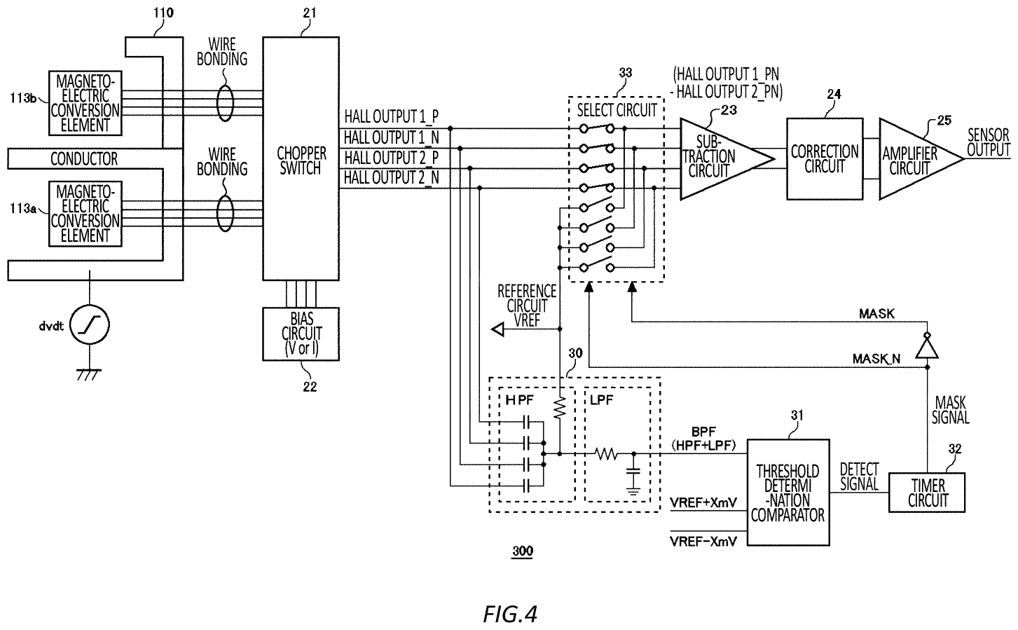

FIG. 3 shows one example of functional blocks of a current sensor 300 including a signal processing IC 120 according to a first embodiment. FIG. 4 is a diagram showing one example of a more specific circuit configuration of the current sensor 300. The signal processing IC 120 includes a bias circuit 22, a subtraction circuit 23, a correction circuit 24, and an amplifier circuit 25. The signal processing IC 120 further includes a common mode voltage detection circuit 30, a threshold determination comparison circuit 31, a timer circuit 32, a select circuit 33, and a reference circuit 34. The signal processing IC 120 is one example of a signal processing unit.

The common mode voltage detection circuit 30 is connected to a pair of first output terminals of a first magnetoelectric conversion element 113a, a pair of second output terminals of a second magnetoelectric conversion element 113b, and the reference circuit 34. The common mode voltage detection circuit 30 detects a common mode voltage obtained by combining a voltage of a first signal outputted from each of the pair of first output terminals of the first magnetoelectric conversion element 113a, and a voltage of a second signal outputted from each of the pair of second output terminals of the second magnetoelectric conversion element 113b. When a transient high voltage (dvdt) is applied to conductors 110, the common mode voltage detection circuit 30 detects and outputs a common mode voltage obtained by combining voltages propagating via respective parasitic capacitances 117.

When the common mode voltage detected by the common mode voltage detection circuit 30 is equal to or lower than a predetermined threshold voltage, the subtraction circuit 23 derives current values of currents flowing through the conductors 110, based on respective first signals and respective second signals. The subtraction circuit 23 is one example of a deriving unit, and may be an adder circuit or may be a differential amplifier circuit depending on the number of sensors and arrangement of conductors.

When the common mode voltage detected by the common mode voltage detection circuit 30 exceeds the threshold voltage, the subtraction circuit 23 masks the respective first signals and the respective second signals, to output a predetermined reference signal different from the first signals and the second signals. As shown in a second embodiment which will be described later, the subtraction circuit 23 may derive the current values of the currents flowing through the conductors 110, based on the respective first signals and the respective second signals after a gain is lowered.

The subtraction circuit 23 may output a signal obtained by replacing the respective first signals and the respective second signals with a predetermined signal, for a predetermined period after the common mode voltage exceeds the predetermined threshold voltage. As shown in the second embodiment which will be described later, the subtraction circuit 23 may derive the current values of the currents flowing through the conductors 110, based on the respective first signals and the respective second signals after a predetermined gain is lowered, for the predetermined period after the common mode voltage exceeds the predetermined threshold voltage.

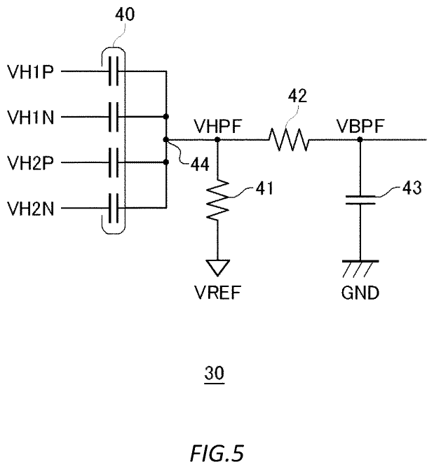

FIG. 5 is a diagram showing one example of a specific circuit configuration of a common mode voltage detection circuit 30. A signal of a voltage VH1P and a signal of a voltage VH1N are outputted from a pair of first output terminals of a first magnetoelectric conversion element 113a. The signal of the voltage VH1P and the signal of the voltage VH1N are examples of a first signal. A signal of a voltage VH2P and a signal of a voltage VH2N are outputted from a pair of second output terminals of a second magnetoelectric conversion element 113b. The signal of the voltage VH2P and the signal of the voltage VH2N are examples of a second signal. The pair of first output terminals and the pair of second output terminals are electrically connected to one ends of detection capacitors 40, respectively. Respective detection capacitors 40 have the same capacitor capacitance. Another ends of the respective detection capacitors 40 are electrically connected to a common node 44. The detection capacitors 40 are examples of first capacitors and second capacitors.

Another ends of the respective detection capacitors 40 are connected to one end of a resistor 41 via the node 44. A reference circuit 34 is connected to another end of the resistor 41, to which a reference voltage VREF is applied.

In addition, one end of the resistor 41 is also connected to one end of a resistor 42. Another end of the resistor 42 is connected to one end of a capacitor 43. Another end of the capacitor 43 is grounded. The capacitor 43 is one example of a third capacitor.

The resistor 41 is connected between the node 44 to which another ends of the respective detection capacitors 40 are connected and an output terminal of the reference circuit 34 which outputs the reference voltage VREF. As a result, the detection capacitors 40 and the resistor 41 can constitute a differentiating circuit which functions as a high pass filter.

Further, the pair of first output terminals of the first magnetoelectric conversion element 113a and the pair of second output terminals of the second magnetoelectric conversion element 113b are respectively connected to the common node 44 via the detection capacitors 40, so that the common mode voltage detection circuit 30 will have a function of detecting a common mode voltage. With such a circuit configuration, a varying voltage excited according to a to-be-measured current I flowing through a conductor 110 is expressed by the following expressions, where a differential output of the first magnetoelectric conversion element 113a is ΔV1, and a differential output of the second magnetoelectric conversion element 113b is ΔV2.

$$Δ V 1 = VH 1 P - VH 1 N \qquad ( 1 )$$

$$Δ V 2 = - ( VH 2 P - VH 2 N ) \qquad ( 2 )$$

From here, assuming that voltages of signals outputted from the pair of first output terminals of the first magnetoelectric conversion element 113a and the pair of second output terminals of the second magnetoelectric conversion element 113b are expressed as ΔV1 and ΔV2, they can be expressed by the following expressions.

$$VH 1 P = Δ V 1 / 2 \qquad ( 3 )$$

$$VH 1 N = - Δ V 1 / 2 \qquad ( 4 )$$

$$VH 2 P = - Δ V 2 / 2 \qquad ( 5 )$$

$$VH 2 N = Δ V 2 / 2 \qquad ( 6 )$$

Here, a voltage VHPF of a signal outputted from the node 44 via the uniform detection capacitors 40 is expressed by the following expression by using the above expressions (3) to (6).

$$VHPF = VH 1 P + VH 1 N + VH 2 P + VH 2 N = Δ V 1 / 2 - Δ V 1 / 2 - Δ V 2 / 2 + Δ V 2 / 2 = 0 \qquad ( 7 )$$

According to Expression (7), the varying voltage excited according to the to-be-measured current I becomes 0, and is not outputted.

On the other hand, assuming that a voltage at which a transient high voltage (dvdt) applied to the conductor 110 propagates via a parasitic capacitance 117 is a voltage ΔVd in the same direction, VH1P, VH1N, VH2P, and VH2N are expressed by the following expression.

$$VH 1 P = Δ Vd \qquad ( 8 )$$

$$VH 1 N = Δ Vd \qquad ( 9 )$$

$$VH 2 P = Δ Vd \qquad ( 10 )$$

$$VH 2 N = Δ Vd \qquad ( 11 )$$

Here, a voltage VHPF of a signal outputted from the node 44 via the uniform detection capacitor 40 is expressed by the following expression by using the above expressions (8) to (11).

$$VHPF = VH 1 P + VH 1 N + VH 2 P + VH 2 N = Δ Vd + Δ Vd + Δ Vd + Δ Vd = Δ4 Vd \qquad ( 12 )$$

As shown in Expression (12), the voltages of the signals outputted from the pair of first output terminals of the first magnetoelectric conversion element 113a and the pair of second output terminals of the second magnetoelectric conversion element 113b to which the transient high voltage (dvdt) has been applied are combined and outputted from the node 44. Accordingly, with such a connection configuration, the common mode voltage detection circuit 30 can detect only the transient high voltage (dvdt).

Up to here, the description has been made in which the pair of first output terminals of the first magnetoelectric conversion element 113a and the pair of second output terminals of the second magnetoelectric conversion element 113b are used. It is clear that, when there is one magnetoelectric conversion element, the common mode voltage detection circuit 30 can perform similar detection when using a pair of output terminals, VH1P and VH1N. In addition, when the signal processing IC 120 selects any two of the pair of first output terminals of the first magnetoelectric conversion element 113a and the pair of second output terminals of the second magnetoelectric conversion element 113b, VH1P, VH1N, VH2P, and VH2N, the signal processing IC 120 can also select any combination in which a varying voltage excited according to the to-be-measured current I becomes 0, according to a positional relationship between the first magnetoelectric conversion element 113a and the second magnetoelectric conversion element 113b, and the conductor 110.

In addition, an integration circuit is configured by connecting the resistor 42 between an output terminal of the common mode voltage detection circuit 30 and the node 44 and connecting the capacitor 43 between the output terminal of the common mode voltage detection circuit 30 and a ground GND. Configuring such an integration circuit can remove unintended high frequency noise.

Although FIG. 4 describes an example in which a low pass filter is configured by using the integration circuit, the integration circuit may not be used. In addition, another filter with any frequency characteristic may be utilized.

In FIG. 3, the threshold determination comparison circuit 31 is connected to the common mode voltage detection circuit 30, and is connected to the reference circuit 34. The threshold determination comparison circuit 31 is supplied with a voltage of VREF±ΔV with respect to the reference voltage VREF supplied to the common mode voltage detection circuit 30, and using a general window comparator circuit, the threshold determination comparison circuit 31 compares |Δ4Vd| and |ΔV|, and when Δ4Vd is greater, the threshold determination comparison circuit 31 outputs a Detect signal by outputting High.

The timer circuit 32 is connected to the threshold determination comparison circuit 31, and counts with any CLK although not clearly shown in FIG. 3. Upon receiving a first Detect signal from the threshold determination comparison circuit 31, the timer circuit 32 changes a Mask signal as an output signal from a Low level to a High level, maintains High level time until a count number reaches a predetermined count number, and then changes the Mask signal from the High level to the Low level. At this time, the timer circuit 32 does not accept second and subsequent Detect signals for a certain period of time. That is, the timer circuit 32 does not accept a Low signal for a certain period, and then at an arbitrary time, the timer circuit 32 is initialized, and performs an operation of accepting the next Detect signal.

Alternatively, upon receiving the first Detect signal from the threshold determination comparison circuit 31, the timer circuit 32 changes the Mask signal as the output signal from the Low level to the High level. Further, upon receiving a second Detect signal, the timer circuit 32 changes the Mask signal from the High level to the Low level, and does not accept third and subsequent Detect signals for a certain period of time. Then at an arbitrary time, the timer circuit 32 is initialized, and performs the operation of accepting the next Detect signal. By performing such an operation, the timer circuit 32 can detect that the transient high voltage (dvdt) has been applied to the conductor 110, and generate the Mask signal only for a predetermined period of time from a moment when the transient high voltage was applied, or a period of time during which the high voltage is applied.

The select circuit 33 is connected to the pair of first output terminals of the first magnetoelectric conversion element 113a, the pair of second output terminals of the second magnetoelectric conversion element 113b, the reference circuit 34, and the timer circuit 32. When the Mask signal is at the Low level, the select circuit 33 selects and outputs from the pair of first output terminals of the first magnetoelectric conversion element 113a and the pair of second output terminals of the second magnetoelectric conversion element 113b. On the other hand, when the Mask signal is at the High level, in order to suppress peaks of a sensor output, the select circuit 33 inputs the same voltages from the reference circuit 34 to selection nodes of the pair of first output terminals of the first magnetoelectric conversion element 113a and the pair of second output terminals of the second magnetoelectric conversion element 113b, and outputs a voltage which makes the to-be-measured current I equivalent to 0. Here, it is assumed that the select circuit 33 outputs the voltage which makes the to-be-measured current I equivalent to 0, but it may output any voltage.

The subtraction circuit 23 is connected to the select circuit 33, and when the Mask signal is at the Low level, the subtraction circuit 23 calculates a current value by cancelling an influence of an externally generated magnetic field (cancelling out common mode noise), based on a difference between outputs of the first magnetoelectric conversion element 113a and the second magnetoelectric conversion element 113b. When the Mask signal is at the High level, the subtraction circuit 23 calculates the voltage which makes the to-be-measured current I equivalent to 0, based on a difference between the same voltages generated by the reference circuit 34.

The correction circuit 24 corrects an output value from the subtraction circuit 23. The correction circuit 24 corrects output values of the first magnetoelectric conversion element 113a and the second magnetoelectric conversion element 113b according to a temperature correction coefficient preliminarily stored in a memory, for example, based on operating temperature. The amplifier circuit 25 amplifies an output value from the correction circuit 24.

In FIG. 4, the bias circuit 22 is a circuit which supplies a current or a voltage to the first magnetoelectric conversion element 113a and the second magnetoelectric conversion element 113b, and the chopper switch 21 performs chopper driving by switching between a pair of input terminals which supply a driving current to the first magnetoelectric conversion element 113a, and a pair of first output terminals, as well as a pair of input terminals which supply a driving current to the second magnetoelectric conversion element 113b, and a pair of second output terminals.

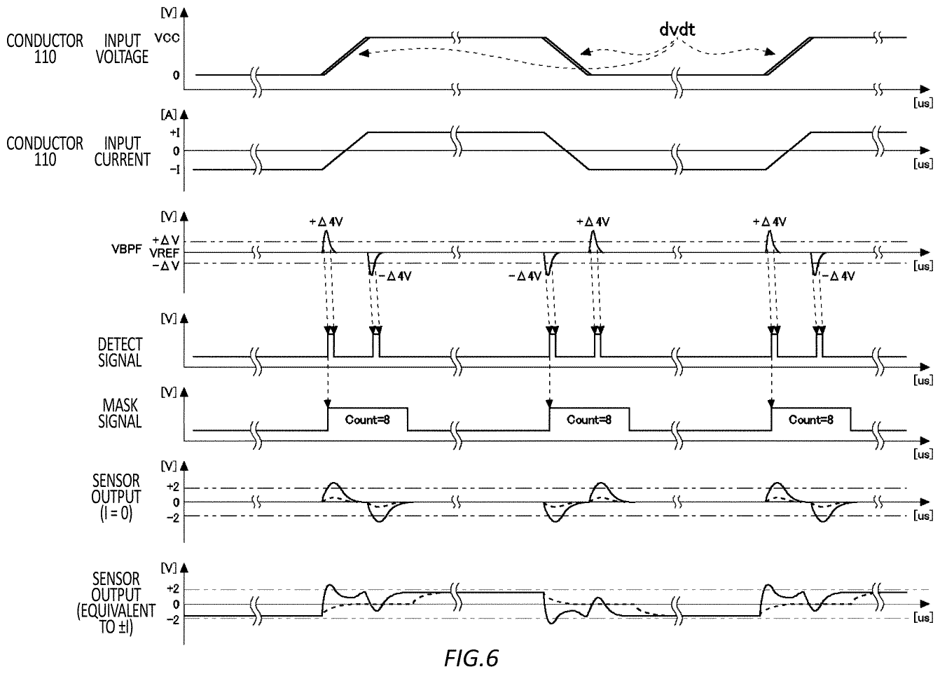

FIG. 6 shows one example of specific operations of the current sensor 300 shown in FIG. 3 and FIG. 5. FIG. 6 shows a series of operations for a case where time widths of a transient high voltage (dvdt) are overlapped when count of the timer circuit 32 is 8 (Count=8) if the transient high voltage (dvdt) is inputted to the conductor 110 in addition to an input current being applied to the conductor 110. As for a sensor output (I=0), a solid line is a sensor output waveform for a case where a Mask signal is not used, and a broken line is a sensor output waveform for a case where the Mask signal is used. If the Mask signal is not used, there is a concern that, when the transient high voltage (dvdt) is inputted, the voltage may exceed voltages (long two-dot chain lines) allowable as the sensor output. If the Mask signal is used, the sensor output waveform is as indicated by the broken line, and peaks of the sensor output are suppressed. In addition, as for a sensor output (equivalent to +I), a solid line is a sensor output waveform for a case where a Mask signal is not used, and a broken line is a sensor output waveform for a case where the Mask signal is used. If the Mask signal is not used, there is a concern that, when the transient high voltage (dvdt) is inputted, the sensor output may be superimposed on the sensor output in response to a current to form a complex sensor output waveform and the voltage may exceed allowable voltages (long two-dot chain lines). If the Mask signal is used, the sensor output waveform is as indicated by the broken line, the sensor output in response to a current is masked, and peaks are suppressed.

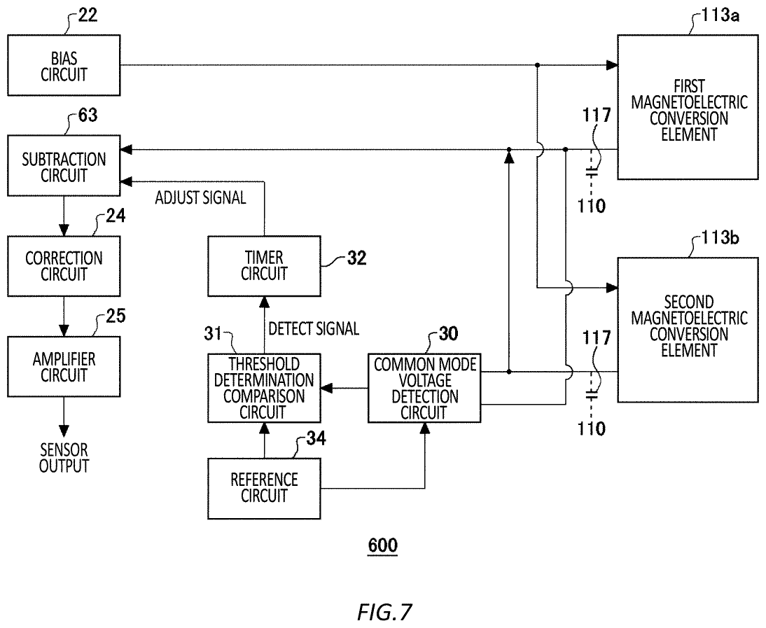

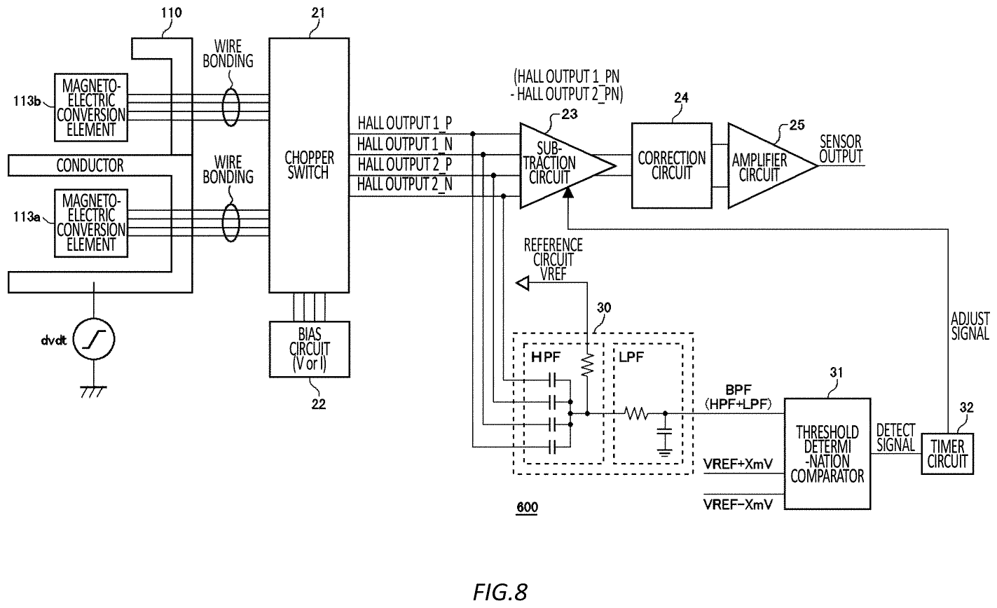

FIG. 7 is a diagram showing one example of functional blocks of a current sensor 600 including a signal processing IC 120 according to a second embodiment. FIG. 8 is a diagram showing one example of a more specific circuit configuration of the current sensor 600. Since the current sensor 600 according to the second embodiment has the same functional blocks as those of the current sensor 300 according to the first embodiment, some of the same functional parts will be omitted from the description.

A timer circuit 32 is connected to a threshold determination comparison circuit 31, and is connected to a subtraction circuit 63 having a function of adjusting a gain. An output signal from the timer circuit 32 is generated by using the same method as the method in the first embodiment. It should be noted that, although the output signal from the timer circuit 32 is utilized as a Mask signal in the first embodiment, it is utilized as an Adjust signal for adjusting the gain in the second embodiment.

The subtraction circuit 63 is connected to a pair of first output terminals of a first magnetoelectric conversion element 113a, a pair of second output terminals of a second magnetoelectric conversion element 113b, and the timer circuit 32. When receiving the Adjust signal at a Low level, the subtraction circuit 63 calculates a current value by cancelling an influence of an externally generated magnetic field (cancelling out common mode noise), based on a difference between outputs of the first magnetoelectric conversion element 113a and outputs of the second magnetoelectric conversion element 113b.

On the other hand, when receiving the Adjust signal at a High level, the subtraction circuit 63 shifts to a predetermined gain and calculates the current value. The gain to be fixed may be a gain setting selected from within a total gain range required as the signal processing IC 120, or may be a separately prepared gain setting outside the range. In either case, in order to suppress peaks of a sensor output, it is desirable that the gain is lower when the Adjust signal is at the High level than when the Adjust signal is at the Low level. In addition, an amplifier circuit 25 may receive the Adjust signal and adjust the gain.

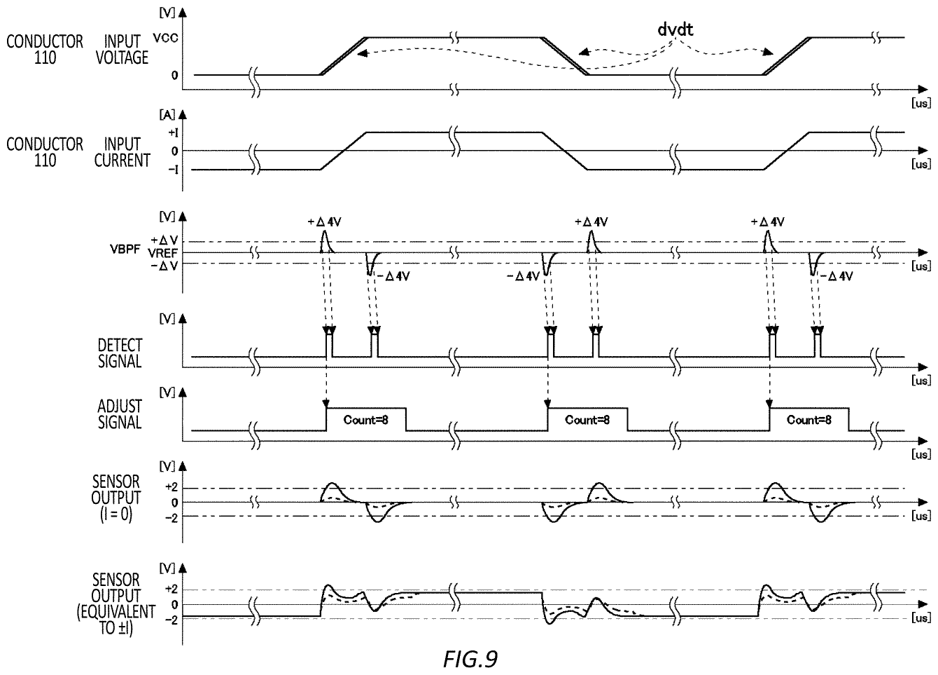

FIG. 9 shows one example of specific operations of the current sensor 600 shown in FIG. 7 and FIG. 8. FIG. 9 shows a series of operations for a case where time widths of a transient high voltage (dvdt) are overlapped when count of the timer circuit 32 is 8 (Count=8) if the transient high voltage (dvdt) is inputted to the conductor 110 in addition to an input current being applied to the conductor 110. As for a sensor output (I=0), a solid line is a sensor output waveform for a case where an Adjust signal is not utilized, and a broken line is a sensor output waveform for a case where the Adjust signal is utilized. An example will be shown in which a gain is set to ½ when the Adjust signal is at a High level. If the Adjust signal is not utilized, there is a concern that, when the transient high voltage (dvdt) is inputted, the voltage may exceed voltages (long two-dot chain lines) allowable as the sensor output. If the Adjust signal is utilized, the sensor output waveform is as indicated by the broken line, and peaks of the sensor output are suppressed. In addition, as for a sensor output (equivalent to +I), a solid line is a sensor output waveform for a case where an Adjust signal is not utilized, and a broken line is a sensor output waveform for a case where the Adjust signal is used. If the Adjust signal is not utilized, there is a concern that, when the transient high voltage (dvdt) is inputted, the sensor output may be superimposed on the sensor output in response to a current to form a complex sensor output waveform and the voltage may exceed allowable voltages (long two-dot chain lines). If the Adjust signal is used, the sensor output waveform is as indicated by the broken line, the sensor output is in response to a current equivalent to ½ current, and peaks are suppressed.

According to the current sensor 600 according to the second embodiment, lowering the gain within a range of no influence can accelerate a return to operation after the application of the transient high voltage (dvdt). In addition, according to the current sensor 600 according to the second embodiment, there is no need for input switching performed, as in the current sensor 300 in the first embodiment, by the select circuit 33 using a switch or the like, and a continuous operation can be performed. Fluctuation in a circuit operating point is small. From the above, the current sensor 600 according to the second embodiment can accelerate the return compared to the current sensor 300 according to the first embodiment.

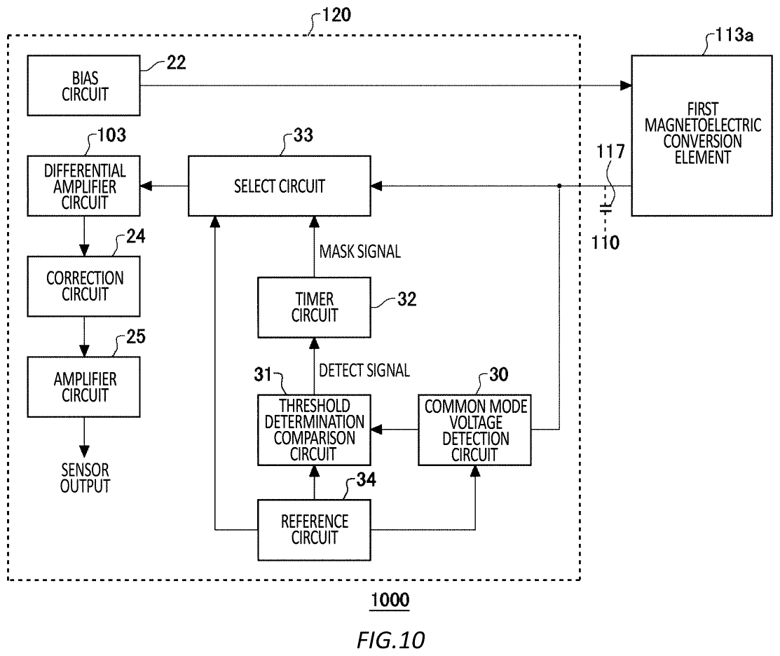

FIG. 10 shows one example of functional blocks of a current sensor 1000 including a signal processing IC 120 according to a third embodiment. This is an embodiment in which the second magnetoelectric conversion element 113b in FIG. 3 is not used, and is one example of functional blocks in which the subtraction circuit 23 is replaced with a differential amplifier circuit 103. Since the current sensor 1000 according to the third embodiment has the same functional blocks as those of the current sensor 300 according to the first embodiment, some of the same functional parts will be omitted from the description.

The differential amplifier circuit 103 is connected to a select circuit 33, and when a Mask signal is at a Low level, the differential amplifier circuit 103 performs amplification with a predetermined gain and calculates a current value, based on an output of the a first magnetoelectric conversion element 113a. When the Mask signal is at a High level, the differential amplifier circuit 103 calculates a voltage which makes a to-be-measured current I equivalent to 0, based on a difference between the same voltages generated by a reference circuit 34.

A common mode voltage detection circuit 30 is connected to a pair of output terminals of the first magnetoelectric conversion element 113a, and as mentioned above, it is clear that the common mode voltage detection circuit 30 can perform similar detection when using a pair of output terminals, VH1P and VH1N.

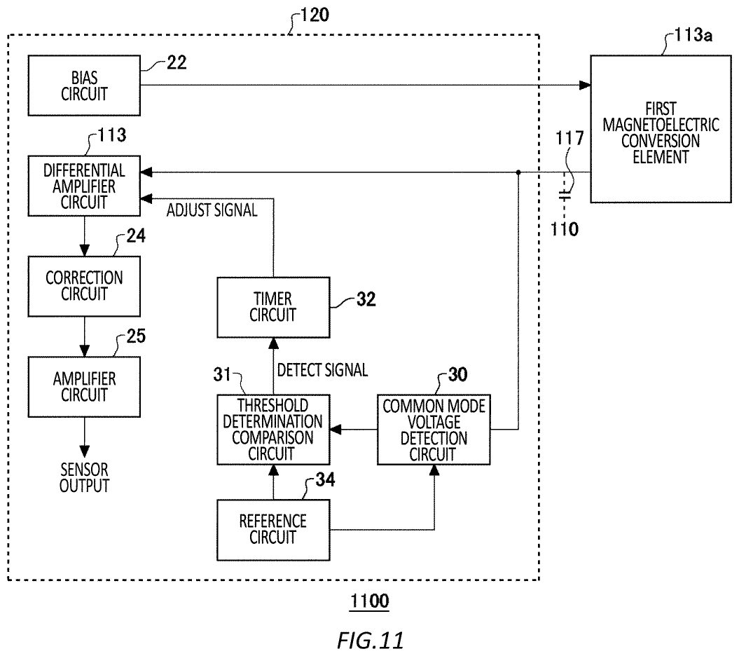

FIG. 11 shows one example of functional blocks of a current sensor 1100 including a signal processing IC 120 according to a fourth embodiment. This is an embodiment in which the second magnetoelectric conversion element 113b in FIG. 7 is not used, and is one example of functional blocks in which the subtraction circuit 63 is replaced with a differential amplifier circuit 113. Since the current sensor 1100 according to the third embodiment has the same functional blocks as those of the current sensor 600 according to the second embodiment, some of the same functional parts will be omitted from the description.

The differential amplifier circuit 113 is connected to a pair of output terminals of a first magnetoelectric conversion element 113a, and when receiving an Adjust signal at a High level, it shifts to a predetermined gain and calculates a current value. The predetermined gain may be set to a gain selected from within a total gain range required as the signal processing IC 120, or may be set to a separately prepared gain outside the range. In either case, in order to suppress peaks of a sensor output, it is desirable that the gain is lower when the Adjust signal is at the High level than when the Adjust signal is at a Low level. In addition, an amplifier circuit 25 may receive the Adjust signal and adjust the gain.

According to the current sensor 1000 according to the third embodiment and the current sensor 1100 according to the fourth embodiment, for an installation location where an influence of the disturbance magnetizing field is small or when a disturbance magnetizing field can be suppressed with a mechanism such as a magnetic shield, there is no need to use a plurality of magnetoelectric conversion elements, and a differential amplifier circuit can be used instead of a subtraction circuit, so the number of related circuits can be reduced, and low current consumption and reduction of a die cost can be realized.

While the present invention has been described above by using the embodiments, the technical scope of the present invention is not limited to the scope of the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

21: chopper switch
22: bias circuit
23: subtraction circuit
24: correction circuit
25: amplifier circuit
30: common mode voltage detection circuit
31: threshold determination comparison circuit
32: timer circuit
33: select circuit
34: reference circuit
40: detection capacitor
41: resistor
42: resistor
43: capacitor
44: node
63: subtraction circuit
103, 113: differential amplifier circuit
100, 300, 600, 1000, 1100: current sensor
101: level difference
110: conductor
110a: gap
110b: gap
111: current path
112a: lead terminal
112b: lead terminal
113a: first magnetoelectric conversion element
113b: second magnetoelectric conversion element
114: insulating member
116: magnetosensitive surface
117: parasitic capacitance
120: signal processing IC
130: metal plate
141: lead terminal
150, 160: wire
180: mold resin
300: current sensor
600: current sensor.

What is claimed is:

1. A current sensor comprising:
a conductor through which a current to be measured flows;
a first magnetoelectric conversion element which is arranged with the conductor as an intermediate and outputs a signal according to a magnetizing field; and
a signal processing circuit having a pair of first input terminals connected to a pair of first output terminals of the first magnetoelectric conversion element via a pair of first conductive wires, wherein
the signal processing circuit has:
a voltage detection circuit which detects a common mode voltage obtained by combining voltages of first signals respectively outputted from the pair of first output terminals;
a differential amplifier circuit which outputs a signal obtained by amplifying each of the first signals with a predetermined gain, when the common mode voltage is equal to or lower than a predetermined threshold voltage, and which outputs a signal obtained by amplifying each of the first signals with a gain lower than a predetermined gain, when the common mode voltage exceeds the predetermined threshold voltage; and
a correction circuit which corrects an output signal of the differential amplifier circuit, and
the signal processing circuit derives a current value of the current flowing through the conductor, based on the output signal corrected by the correction circuit.

2. The current sensor according to claim 1, further comprising a second magnetoelectric conversion element which is arranged opposite to the first magnetoelectric conversion element with the conductor interposed therebetween and outputs a signal according to a magnetizing field, wherein
the signal processing circuit further has a pair of second input terminals which are connected to a pair of second output terminals of the second magnetoelectric conversion element via a pair of second conductive wires,
the voltage detection circuit detects a common mode voltage obtained by combining voltages of two or more signals, among the voltages of the first signals respectively outputted from the pair of first output terminals and voltages of second signals respectively outputted from the pair of second output terminals, and
the differential amplifier circuit has a subtraction circuit which amplifies each of the first signals and each of the second signals with a predetermined gain and outputs a difference between the first signals amplified and the second signals amplified, when the common mode voltage is equal to or lower than the predetermined threshold voltage, and which amplifies each of the first signals and each of the second signals with a gain lower than a predetermined gain and outputs a difference between the first signals amplified and the second signals amplified, when the common mode voltage exceeds the predetermined threshold voltage.

3. The current sensor according to claim 2, wherein the signal processing circuit derives the current value of the current flowing through the conductor, based on each of the first signals and each of the second signals after a gain is lowered, for a predetermined period after the common mode voltage exceeds the predetermined threshold voltage.

4. The current sensor according to claim 2, wherein the voltage detection circuit has a noise reduction circuit which reduces noise in each of the first signals and each of the second signals.

5. The current sensor according to claim 4, wherein the noise reduction circuit includes a high pass filter and a low pass filter.

6. The current sensor according to claim 5, wherein
the high pass filter includes:
a pair of first capacitors having one ends electrically connected to the pair of first input terminals respectively;
a pair of second capacitors having one ends electrically connected to the pair of second input terminals respectively; and
a first resistor having one end connected to another end of each of the pair of first capacitors and to another end of each of the pair of second capacitors and having another end to which a reference voltage is applied,
the low pass filter includes:
a second resistor having one end connected to the another end of the first resistor; and
a third capacitor having one end connected to another end of the second resistor and having another end being grounded, and
the voltage detection circuit outputs the common mode voltage from the another end of the second resistor.

7. A current sensor comprising:
a conductor through which a current to be measured flows;
a first magnetoelectric conversion element which is arranged with the conductor as an intermediate and outputs a signal according to a magnetizing field; and
a signal processing circuit having a pair of first input terminals connected to a pair of first output terminals of the first magnetoelectric conversion element via a pair of first conductive wires, wherein
the signal processing circuit has:
a voltage detection circuit which detects a common mode voltage obtained by combining voltages of first signals respectively outputted from the pair of first output terminals;
a select circuit which outputs a signal obtained by replacing each of the first signals with a predetermined signal, when the common mode voltage exceeds a predetermined threshold voltage, and which outputs each of the first signals, when the common mode voltage is equal to or lower than a predetermined threshold voltage;
a differential amplifier circuit which amplifies an output signal of the select circuit with a predetermined gain, when the common mode voltage is equal to or lower than the predetermined threshold voltage; and
a correction circuit which corrects an output signal of the differential amplifier circuit, and
the signal processing circuit derives a current value of the current flowing through the conductor, based on the output signal corrected by the correction circuit.

8. The current sensor according to claim 1, wherein the signal processing circuit is arranged on a metal plate insulated from the conductor.

9. The current sensor according to claim 1, wherein the pair of first conductive wires are wired across the conductor.

10. The current sensor according to claim 7, further comprising a second magnetoelectric conversion element which is arranged opposite to the first magnetoelectric conversion element with the conductor interposed therebetween and outputs a signal according to a magnetizing field, wherein
the signal processing circuit further has a pair of second input terminals which are connected to a pair of second output terminals of the second magnetoelectric conversion element via a pair of second conductive wires,
the voltage detection circuit detects a common mode voltage obtained by combining voltages of two or more signals, among the voltages of the first signals respectively outputted from the pair of first output terminals and voltages of second signals respectively outputted from the pair of second output terminals, and
the differential amplifier circuit has a subtraction circuit which amplifies each of the first signals and each of the second signals with a predetermined gain and outputs a difference between the first signals amplified and the second signals amplified, when the common mode voltage is equal to or lower than the predetermined threshold voltage,
and which outputs a signal obtained by replacing each of the first signals and each of the second signals with a predetermined signal, when the common mode voltage exceeds the predetermined threshold voltage.

11. The current sensor according to claim 10, wherein the signal processing circuit outputs a signal obtained by replacing each of the first signals and each of the second signals with a predetermined signal, for a predetermined period after the common mode voltage exceeds the predetermined threshold voltage.

12. The current sensor according to claim 10, wherein the voltage detection circuit has a noise reduction circuit which reduces noise in each of the first signals and each of the second signals.

13. The current sensor according to claim 12, wherein the noise reduction circuit includes a high pass filter and a low pass filter.

14. The current sensor according to claim 13, wherein
the high pass filter includes:
a pair of first capacitors having one ends electrically connected to the pair of first input terminals respectively;
a pair of second capacitors having one ends electrically connected to the pair of second input terminals respectively; and
a first resistor having one end connected to another end of each of the pair of first capacitors and to another end of each of the pair of second capacitors and having another end to which a reference voltage is applied,
the low pass filter includes:
a second resistor having one end connected to the another end of the first resistor; and
a third capacitor having one end connected to another end of the second resistor and having another end being grounded, and
the voltage detection circuit outputs the common mode voltage from the another end of the second resistor.

15. The current sensor according to claim 8, wherein the signal processing circuit is arranged on a metal plate insulated from the conductor.

16. The current sensor according to claim 8, wherein the pair of first conductive wires are wired across the conductor.

17. A method for detecting currents according to magnetizing fields detected by a first magnetoelectric conversion element and a second magnetoelectric conversion element which are arranged opposite to each other with a conductor through which a current to be measured flows, interposed therebetween, the method comprising:
detecting a common mode voltage by combining two or more signals, among a pair of first output signals of the first magnetoelectric conversion element and a pair of second output signals of the second magnetoelectric conversion element;
comparing the common mode voltage with a predetermined threshold voltage;
outputting, as a correction signal, a signal obtained by lowering a gain of each of the pair of first output signals and the pair of second output signals, or a signal obtained by replacing each of the pair of first output signals and the pair of second output signals with a predetermined signal, when the common mode voltage exceeds the predetermined threshold voltage;
outputting, as the correction signal, each of the pair of first output signals and the pair of second output signals, when the common mode voltage is equal to or lower than the predetermined threshold voltage; and
deriving a current value of the current flowing through the conductor, based on the correction signal.

18. The method for detecting currents according to claim 17, comprising outputting, as the correction signal, a signal obtained by lowering a gain of each of the pair of first output signals and the pair of second output signals, or a signal obtained by replacing each of the pair of first output signals and the pair of second output signals with a predetermined signal, for a predetermined period after the common mode voltage exceeds the predetermined threshold voltage, when the common mode voltage exceeds the predetermined threshold voltage.

19. The method for detecting currents according to claim 17, wherein the detecting a common mode voltage includes reducing noise in the pair of first output signals and the pair of second output signals.

20. The method for detecting currents according to claim 19, the reducing noise includes reducing the noise in the pair of first output signals and the pair of second output signals with a high pass filter and a low pass filter.
